(19) United States
(12) Patent Application Publication
(10) Pub. No.: US 2024/0266329 A1
(43) Pub. Date: Aug. 8, 2024

(54) DISPLAY DEVICE USING SEMICONDUCTOR LIGHT-EMITTING ELEMENT, AND MANUFACTURING METHOD THEREFOR

(71) Applicant: LG ELECTRONICS INC., Seoul (KR)

(72) Inventors: Junoh SHIN, Seoul (KR); Byoungkwon CHO, Seoul (KR); Wonseok CHOI, Seoul (KR); Jeonghyo KWON, Seoul (KR)

(73) Assignee: LG ELECTRONICS INC., Seoul (KR)

(21) Appl. No.: 18/580,914

(22) PCT Filed: Jul. 22, 2021
(86) PCT No.: PCT/KR2021/009456

§ 371 Date: Jan. 19, 2024

(51) Int. Cl. H01L 25/075; H01L 33/00; H01L 33/38; H01L 33/44

(52) U.S. Cl. CPC H01L 25/0753; H01L 33/0093; H01L 33/38; H01L 33/44; H01L 2224/95133; H01L 2933/0016

(57) ABSTRACT

The present disclosure is applicable to a technical field related to display devices, and relates to a display device using, for example, a micro light emitting diode (LED), and a manufacturing method therefor. The present disclosure may comprise: a substrate; a partition defining a unit pixel region; a first electrode located in the unit pixel region; a semiconductor light-emitting element electrically connecting a first-type electrode to the first electrode and provided in the unit pixel region; an inclined a layer formed on the semiconductor light-emitting element and the partition, and having a high incline on the semiconductor light-emitting element; and a second electrode electrically connected, on the inclined coating layer, to a second-type electrode of the semiconductor light-emitting element.

### TECHNICAL FIELD

The present disclosure relates to a technical field related to a display device, for example, a display device using a micro light emitting diode (LED) and a manufacturing method thereof.

### BACKGROUND

Recently, in a field of a display technology, display devices having excellent characteristics such as thinness, flexibility, and the like have been developed. On the other hand, currently commercialized major displays are represented by a LCD (liquid crystal display) and an OLED (organic light emitting diode).

On the other hand, LED (light emitting diode), which is a well-known semiconductor light emitting element that converts electric current into light, has been used as a light source for a display image of an electronic device including an information and communication device along with a GaP:N-based green LED, starting with commercialization of a red LED using a GaAsP compound semiconductor in 1962. Accordingly, a method for solving the above-described problems by implementing a display using the semiconductor light emitting element may be proposed.

Recently, such light emitting diode (LED) has been gradually miniaturized and manufactured into a micro-sized LED to be used as a pixel of the display device.

Such micro LED technology exhibits characteristics of low power, high brightness, and high reliability compared to other display devices/panels, and is able to be applied to a flexible device as well. Therefore, in recent years, research institutes and companies have been actively researching the micro LED.

A recent issue in relation to the micro LED is a technology to transfer the LED to a panel. Many LEDs are used to manufacture one display device using the micro LEDs, but it is very difficult and time-consuming to manufacture the display device by attaching the LEDs to the panel one by one.

When a micro LED is assembled, the micro LED may be inclined at a position of a unit element area.

According to a conventional display manufacturing process, three masks may be used while a passivation opening, a planarization, and a lighting wire forming process are performed in a post-process after the micro LED is assembled

A photo process using the three masks may be accumulated, and an error due to alignment tolerance for each process may be accumulated. Such accumulation of errors may lead to problems such as luminance non-uniformity and unlighting of a display device. In addition, due to the accumulation of the alignment error, problems such as luminance non-uniformity and non-lighting of the display device may be further increased.

Therefore, there is a need to resolve problems that occur when manufacturing a display using such a micro LED.

### DETAILED DESCRIPTION

### Technical Solution

An object of the present disclosure is to provide a display device using a semiconductor light emitting device and a manufacturing method thereof for minimizing alignment tolerances that may occur in a panel photo process by simplifying a manufacturing process by improving a design of the semiconductor light emitting device and the panel process. and a manufacturing method thereof.

An object of the present disclosure is to provide a display device using a semiconductor light emitting device and a manufacturing method thereof for shortening the number of processes for connecting the semiconductor light emitting device and an upper wiring.

An object of the present disclosure is to provide a display device using a semiconductor light emitting device and a manufacturing method thereof for ensuring the maximum contact area of a semiconductor light emitting device chip electrode and a second electrode (upper wiring: lighting electrode) by minimizing an alignment error in a post-panel process.

### Technical Solution

To achieve the object of the present disclosure, according to a first aspect of the present disclosure, a display device includes a substrate, a partition wall defining a unit pixel area, a first electrode disposed in the unit pixel area, a semiconductor light emitting device installed with a first-type electrode electrically connected to the first electrode within the unit pixel area, an inclined coating layer formed on the semiconductor light emitting device and the partition wall and having a high inclination at an upper side of the semiconductor light emitting device, and a second electrode electrically connected to a second-type electrode of the semiconductor light emitting device on the inclined coating layer.

The inclined coating layer may have a symmetrical inclination with respect to the unit pixel area in which the semiconductor light emitting device is installed.

The inclined coating layer may be formed of a photoresist with a lower viscosity than a material of the partition wall.

A thickness of a portion of the inclined coating layer, disposed on the partition wall, may be less than a thickness of a portion of the inclined coating layer, disposed on the semiconductor light emitting device.

The semiconductor light emitting device may include the first-type electrode, a semiconductor layer disposed on the first-type electrode, the second-type electrode disposed on the semiconductor layer, and a passivation layer disposed on an outer surface of the semiconductor layer and the second-type electrode.

The passivation layer may include an alignment adjuster disposed higher than the second-type electrode on a peripheral portion of the second-type electrode.

The alignment adjuster may be partially removed together when the inclined coating layer is opened for connection of the second electrode.

A height of the alignment adjuster may be equal to or less than 100 nm.

An assembly electrode for assembly of the semiconductor light emitting device may be disposed at one side of the first electrode of the unit pixel area.

To achieve the object of the present disclosure, according to a second aspect of the present disclosure, a method of manufacturing a display device using a semiconductor light emitting device includes preparing a substrate assembly including a substrate on which a partition wall defining a plurality of unit pixel area is defined wherein a first electrode and an assembly electrode are disposed within the unit pixel area, preparing a plurality of semiconductor light emitting devices in which a semiconductor layer and a second-type electrode are disposed on a first-type electrode, and a passivation layer is formed on an outer surface of the semiconductor layer and the second-type electrode, installing the semiconductor light emitting device to electrically connect the first electrode and the first-type electrode to each other within the unit pixel area, forming an inclined coating layer on the semiconductor light emitting device and the partition wall, opening the second-type electrode of the semiconductor light emitting device by entirely etching the inclined coating layer, and forming a second electrode electrically connected to the second-type electrode of the semiconductor light emitting device on the inclined coating layer.

The opening of the second-type electrode may include opening the second-type electrode of the semiconductor light emitting device installed within each of the unit pixel areas.

The inclined coating layer may have a high inclination at an upper side of the semiconductor light emitting device.

The forming of the inclined coating layer may include coating a photoresist with a lower viscosity than a material of the partition wall.

The preparing of the semiconductor light emitting device may include forming the passivation layer to cover an upper side of the second-type electrode.

A thickness of a portion of the passivation layer, covering the upper side of the second-type electrode, may be less than a thickness of a portion of the passivation layer, disposed on an outer surface of the semiconductor light emitting device.

The preparing of the semiconductor light emitting device may include opening the second-type electrode by removing the passivation layer covering the upper side of the second-type electrode, and forming a passivation layer having a smaller thickness than the passivation layer disposed on an outer surface of the semiconductor light emitting device on the second-type electrode.

The passivation layer may include an alignment adjuster disposed higher than the second-type electrode on a peripheral portion of the second-type electrode.

The alignment adjuster may have a height that is lowered after the opening of the second-type electrode is performed.

A height of the alignment adjuster may be equal to or less than 100 nm.

The installing of the semiconductor light emitting device may include applying an electric field to the assembly electrode.

### Advantageous Effects

According to an embodiment of the present disclosure, the following effects are obtained.

First, according to an embodiment of the present disclosure, a manufacturing process is simplified through design and panel process improvement of a semiconductor light emitting device, thereby minimizing alignment tolerance which may occur in a panel photo process, thereby improving manufacturing yield.

In detail, when the semiconductor light emitting device chip is fixed by forming the inclined coating layer using a low viscosity photoresist, planarization of a metal wiring may be simultaneously performed when the second electrode (upper wiring: the lighting electrode) is connected. Accordingly, the photo process may be simplified from three operations to one operation.

An alignment error may be minimized in a post-panel process to ensure a maximum contact area of the semiconductor light emitting device chip electrode and the second electrode (upper wiring: the lighting electrode).

Therefore, when the semiconductor light emitting device chip is assembled at the right position of the chip, the semiconductor light emitting device chip electrode having a size of about 3 μm may be connected to the wire, and the alignment error may be minimized to allow the semiconductor light emitting device chip to be connected to the side surface even though the semiconductor light emitting device chip is positioned on the side surface.

Furthermore, according to another embodiment of the present disclosure, there are additional technical effects not mentioned herein. One of ordinary skill in the art may understand the effects through the application of the specification and drawings.

### BRIEF DESCRIPTION OF THE DRAWINGS

FIG. 1 is a conceptual diagram illustrating an embodiment of a display device using a semiconductor light emitting device according to the present disclosure;

FIG. 2 is a partially enlarged diagram showing a part A shown in FIG. 1.

FIGS. 3A and 3B are cross-sectional diagrams taken along the cutting lines B-B and C-C in FIG. 2:

FIG. 4 is a conceptual diagram illustrating the flip-chip type semiconductor light emitting device of FIG. 3:

FIGS. 5A to 5C are conceptual diagrams illustrating various examples of color implementation with respect to a flip-chip type semiconductor light emitting device:

FIG. 6 shows cross-sectional views of a method of fabricating a display device using a semiconductor light emitting device according to the present disclosure:

FIG. 7 is a perspective diagram of a display device using a semiconductor light emitting device according to another embodiment of the present disclosure:

FIG. 8 is a cross-sectional diagram taken along a cutting line D-D shown in FIG. 7:

FIG. 9 is a conceptual diagram showing a vertical type semiconductor light emitting device shown in FIG. 8:

FIG. 10 is a schematic cross-sectional view illustrating an example of a semiconductor light emitting device of a display device using a semiconductor light emitting device according to an embodiment of the present disclosure.

FIG. 11 is a cross-sectional view illustrating a state in which a semiconductor light emitting device is assembled and an inclined coating layer is formed as one operation of a manufacturing process of a display device using a semiconductor light emitting device according to an embodiment of the present disclosure.

FIG. 12 is a cross-sectional schematic view illustrating a method of manufacturing a display device using a semiconductor light emitting device according to an embodiment of the present disclosure, in which an inclined coating layer is opened to open a second-type electrode.

FIG. 13 is a cross-sectional view illustrating a state in which a second electrode electrically connected to a second-type electrode is formed as one operation of a process of manufacturing a display device using a semiconductor light emitting device according to an embodiment of the present disclosure.

FIG. 14 is a diagram illustrating a process of manufacturing a display device using a semiconductor light emitting device as a comparative example.

FIG. 15 is an actual image of an alignment error that may occur in the process of FIG. 14.

FIG. 16 is a schematic diagram illustrating various states in which a lighting wire (second electrode) is connected.

FIG. 17 is a cross-sectional diagram illustrating a shape of an alignment adjusting unit of a semiconductor light emitting device in a process of manufacturing a display device using a semiconductor light emitting device according to an embodiment of the present disclosure.

FIG. 18 is a schematic cross-sectional view illustrating a structure of a pixel according to a comparative example and a structure of a pixel according to an embodiment of the present disclosure.

FIG. 19 is an actual image showing a pixel lighting state in each part of a display device using a semiconductor light emitting device as a comparative example.

FIG. 20 is an actual image showing a pixel lighting state in each part of a display device using a semiconductor light emitting device according to an embodiment of the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting device mentioned in this specification is a concept including an LED, a micro LED, and the like, which may be used in a mixed manner.

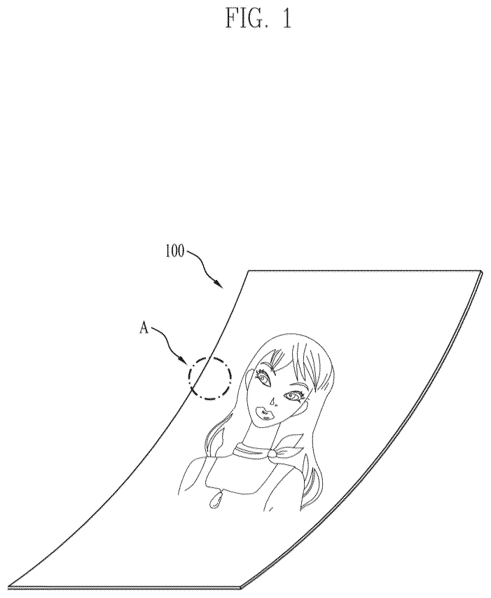

FIG. 1 is a conceptual view illustrating an embodiment of a display device using a semiconductor light emitting device according to the present disclosure.

As shown in FIG. 1, information processed by a controller (not shown) of a display device 100 may be displayed using a flexible display.

The flexible display may include, for example, a display that may be warped, bent, twisted, folded, or rolled by external force.

Furthermore, the flexible display may be, for example, a display manufactured on a thin and flexible substrate that may be warped, bent, folded, or rolled like paper while maintaining the display characteristics of a conventional flat panel display.

When the flexible display remains in an unbent state (e.g., a state having an infinite radius of curvature) (hereinafter referred to as a first state), the display area of the flexible display forms a flat surface. When the display in the first state is changed to a bent state (e.g., a state having a finite radius of curvature) (hereinafter referred to as a second state) by external force, the display area may be a curved surface. As shown in FIG. 1, the information displayed in the second state may be visual information output on a curved surface. Such visual information may be implemented by independently controlling the light emission of sub-pixels arranged in a matrix form. The unit pixel may mean, for example, a minimum unit for implementing one color.

The unit pixel of the flexible display may be implemented by a semiconductor light emitting device. In the present disclosure, a light emitting diode (LED) is exemplified as a type of the semiconductor light emitting device configured to convert electric current into light. The LED may be formed in a small size, and may thus serve as a unit pixel even in the second state.

Hereinafter, a flexible display implemented using the LED will be described in more detail with reference to the drawings.

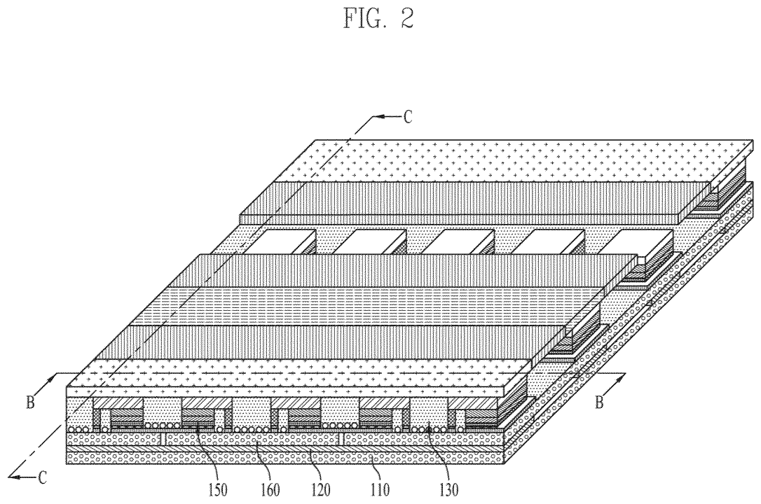

FIG. 2 is a partially enlarged view showing part A of FIG. 1.

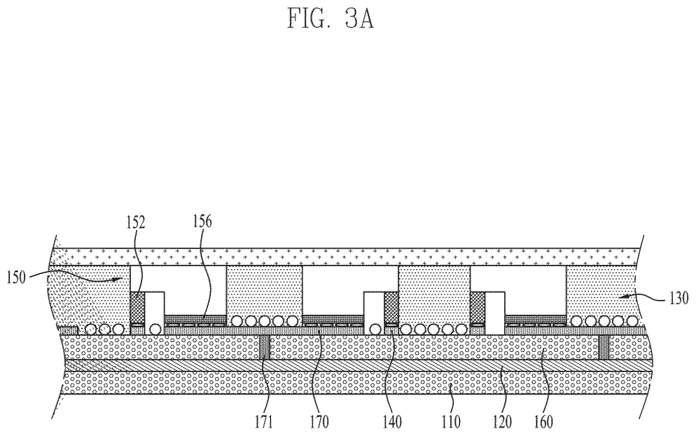

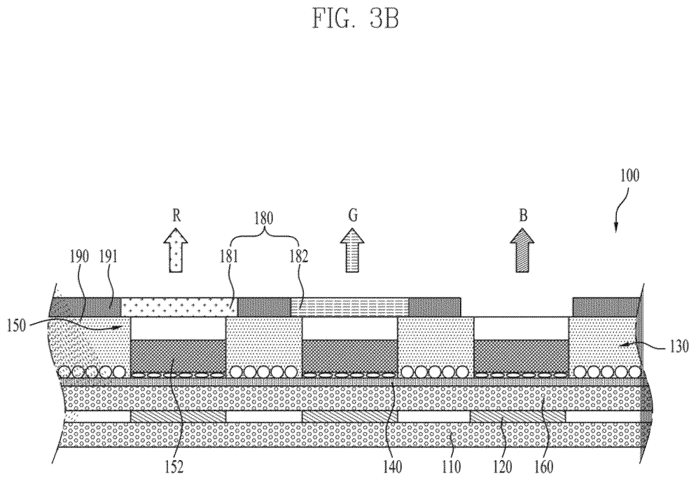

FIGS. 3A and 3B are cross-sectional views taken along lines B-B and C-C in FIG. 2.

As shown in FIGS. 2, 3A and 3B, the display device 100 using a passive matrix (PM) type semiconductor light emitting device is exemplified as the display device 100 using a semiconductor light emitting device. However, the examples described below are also applicable to an active matrix (AM) type semiconductor light emitting device.

The display device 100 shown in FIG. 1 may include a substrate 110, a first electrode 120, a conductive adhesive layer 130, a second electrode 140, and at least one semiconductor light emitting device 150, as shown in FIG. 2.

The substrate 110 may be a flexible substrate. For example, to implement a flexible display device, the substrate 110 may include glass or polyimide (PI). Any insulative and flexible material such as polyethylene naphthalate (PEN) or polyethylene terephthalate (PET) may be employed. In addition, the substrate 110 may be formed of either a transparent material or an opaque material.

The substrate 110 may be a wiring substrate on which the first electrode 120 is disposed. Thus, the first electrode 120 may be positioned on the substrate 110.

As shown in FIG. 3A, an insulating layer 160 may be disposed on the substrate 110 on which the first electrode 120 is positioned, and an auxiliary electrode 170 may be positioned on the insulating layer 160. In this case, a stack in which the insulating layer 160 is laminated on the substrate 110 may be a single wiring substrate. More specifically, the insulating layer 160 may be formed of an insulative and flexible material such as PI, PET, or PEN, and may be integrated with the substrate 110 to form a single substrate.

The auxiliary electrode 170, which is an electrode that electrically connects the first electrode 120 and the semiconductor light emitting device 150, is positioned on the insulating layer 160, and is disposed to correspond to the position of the first electrode 120. For example, the auxiliary electrode 170 may have a dot shape and may be electrically connected to the first electrode 120 by an electrode hole 171 formed through the insulating layer 160. The electrode hole 171 may be formed by filling a via hole with a conductive material.

As shown in FIG. 2 or 3A, a conductive adhesive layer 130 may be formed on one surface of the insulating layer 160, but embodiments of the present disclosure are not limited thereto. For example, a layer performing a specific function may be formed between the insulating layer 160 and the conductive adhesive layer 130, or the conductive adhesive layer 130 may be disposed on the substrate 110 without the insulating layer 160. In a structure in which the conductive adhesive layer 130 is disposed on the substrate 110, the conductive adhesive layer 130 may serve as an insulating layer.

The conductive adhesive layer 130 may be a layer having adhesiveness and conductivity. For this purpose, a material having conductivity and a material having adhesiveness may be mixed in the conductive adhesive layer 130. In addition, the conductive adhesive layer 130 may have ductility, thereby providing making the display device flexible.

As an example, the conductive adhesive layer 130 may be an anisotropic conductive film (ACF), an anisotropic conductive paste, a solution containing conductive particles, or the like. The conductive adhesive layer 130 may be configured as a layer that allows electrical interconnection in the direction of the Z-axis extending through the thickness, but is electrically insulative in the horizontal X-Y direction. Accordingly, the conductive adhesive layer 130 may be referred to as a Z-axis conductive layer (hereinafter, referred to simply as a “conductive adhesive layer”).

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

The ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may be composed of a plurality of layers with conductive balls arranged on one of the layers (as a double-ACF).

The anisotropic conductive paste may be a combination of a paste and conductive balls, and may be a paste in which conductive balls are mixed with an insulating and adhesive base material. Also, the solution containing conductive particles may be a solution containing any conductive particles or nanoparticles.

Referring back to FIG. 3A, the second electrode 140 is positioned on the insulating layer 160 and spaced apart from the auxiliary electrode 170. That is, the conductive adhesive layer 130 is disposed on the insulating layer 160 having the auxiliary electrode 170 and the second electrode 140 positioned thereon.

After the conductive adhesive layer 130 is formed with the auxiliary electrode 170 and the second electrode 140 positioned on the insulating layer 160, the semiconductor light emitting device 150 is connected thereto in a flip-chip form by applying heat and pressure. Thereby, the semiconductor light emitting device 150 is electrically connected to the first electrode 120 and the second electrode 140.

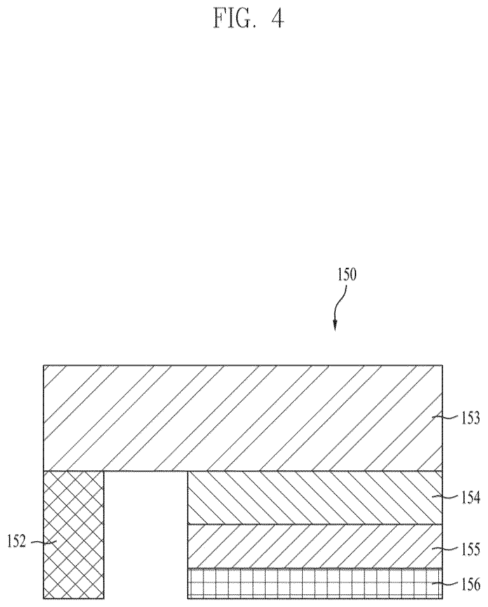

FIG. 4 is a conceptual view illustrating the flip-chip type semiconductor light emitting device of FIG. 3.

Referring to FIG. 4, the semiconductor light emitting device may be a flip chip-type light emitting device.

For example, the semiconductor light emitting device may include a p-type electrode 156, a p-type semiconductor layer 155 on which the p-type electrode 156 is formed, an active layer 154 formed on the p-type semiconductor layer 155, an n-type semiconductor layer 153 formed on the active layer 154, and an n-type electrode 152 disposed on the n-type semiconductor layer 153 and horizontally spaced apart from the p-type electrode 156. In this case, the p-type electrode 156 may be electrically connected to the auxiliary electrode 170, which is shown in FIG. 3, by the conductive adhesive layer 130, and the n-type electrode 152 may be electrically connected to the second electrode 140.

Referring back to FIGS. 2, 3A and 3B, the auxiliary electrode 170 may be elongated in one direction. Thus, one auxiliary electrode may be electrically connected to the plurality of semiconductor light emitting devices 150. For example, p-type electrodes of semiconductor light emitting devices on left and right sides of an auxiliary electrode may be electrically connected to one auxiliary electrode.

More specifically, the semiconductor light emitting device 150 may be press-fitted into the conductive adhesive layer 130 by heat and pressure. Thereby, only the portions of the semiconductor light emitting device 150 between the p-type electrode 156 and the auxiliary electrode 170 and between the n-type electrode 152 and the second electrode 140 may exhibit conductivity; and the other portions of the semiconductor light emitting device 150 do not exhibit conductivity as they are not press-fitted. In this way, the conductive adhesive layer 130 interconnects and electrically connects the semiconductor light emitting device 150 and the auxiliary electrode 170 and interconnects and electrically connects the semiconductor light emitting device 150 and the second electrode 140.

The plurality of semiconductor light emitting devices 150 may constitute a light emitting device array, and a phosphor conversion layer 180 may be formed on the light emitting device array.

The light emitting device array may include a plurality of semiconductor light emitting devices having different luminance values. Each semiconductor light emitting device 150 may constitute a unit pixel and may be electrically connected to the first electrode 120. For example, a plurality of first electrodes 120 may be provided, and the semiconductor light emitting devices may be arranged in, for example, several columns. The semiconductor light emitting devices in each column may be electrically connected to any one of the plurality of first electrodes.

In addition, since the semiconductor light emitting devices are connected in a flip-chip form, semiconductor light emitting devices grown on a transparent dielectric substrate may be used. The semiconductor light emitting devices may be, for example, nitride semiconductor light emitting devices. Since the semiconductor light emitting device 150 has excellent luminance, it may constitute an individual unit pixel even when it has a small size.

As shown in FIGS. 3a and 3b, a partition wall 190 may be formed between the semiconductor light emitting devices 150. In this case, the partition wall 190 may serve to separate individual unit pixels from each other, and may be integrated with the conductive adhesive layer 130. For example, by inserting the semiconductor light emitting device 150 into the ACF, the base member of the ACF may form the partition wall.

In addition, when the base member of the ACF is black, the partition wall 190 may have reflectance and increase contrast even without a separate black insulator.

As another example, a reflective partition wall may be separately provided as the partition wall 190. In this case, the partition wall 190 may include a black or white insulator depending on the purpose of the display device. When a partition wall including a white insulator is used, reflectivity may be increased. When a partition wall including a black insulator is used, it may have reflectance and increase contrast.

The phosphor conversion layer 180 may be positioned on the outer surface of the semiconductor light emitting device 150. For example, the semiconductor light emitting device 150 may be a blue semiconductor light emitting device that emits blue (B) light, and the phosphor conversion layer 180 may function to convert the blue (B) light into a color of a unit pixel. The phosphor conversion layer 180 may be a red phosphor 181 or a green phosphor 182 constituting an individual pixel.

That is, the red phosphor 181 capable of converting blue light into red (R) light may be laminated on a blue semiconductor light emitting device at a position of a unit pixel of red color, and the green phosphor 182 capable of converting blue light into green (G) light may be laminated on the blue semiconductor light emitting device at a position of a unit pixel of green color. Only the blue semiconductor light emitting device may be used alone in the portion constituting the unit pixel of blue color. In this case, unit pixels of red (R), green (G), and blue (B) may constitute one pixel. More specifically, a phosphor of one color may be laminated along each line of the first electrode 120. Accordingly, one line on the first electrode 120 may be an electrode for controlling one color. That is, red (R), green (G), and blue (B) may be sequentially disposed along the second electrode 140, thereby implementing a unit pixel.

However, embodiments of the present disclosure are not limited thereto. Unit pixels of red (R), green (G), and blue (B) may be implemented by combining the semiconductor light emitting device 150 and the quantum dot (QD) rather than using the phosphor.

Also, a black matrix 191 may be disposed between the phosphor conversion layers to improve contrast. That is, the black matrix 191 may improve contrast of light and darkness.

However, embodiments of the present disclosure are not limited thereto, and anther structure may be applied to implement blue, red, and green colors.

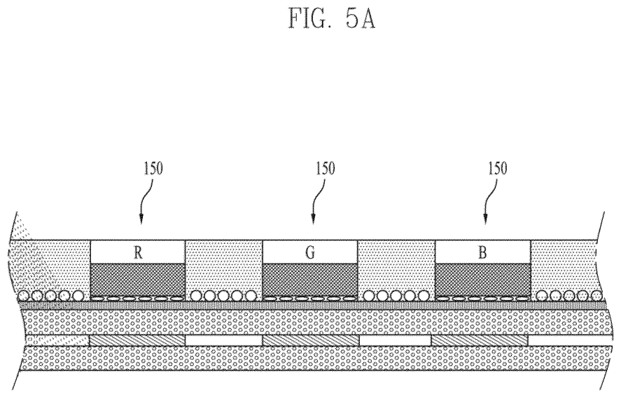

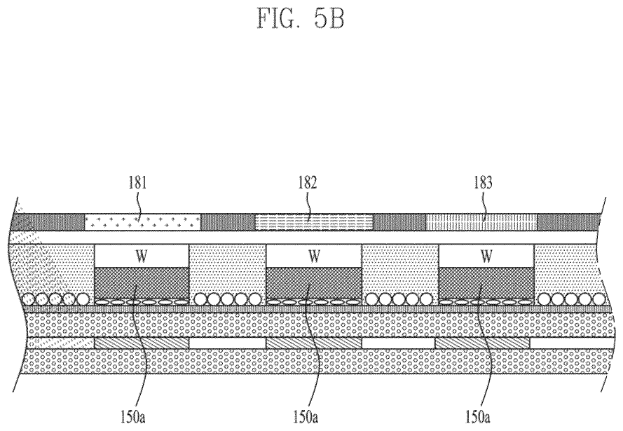

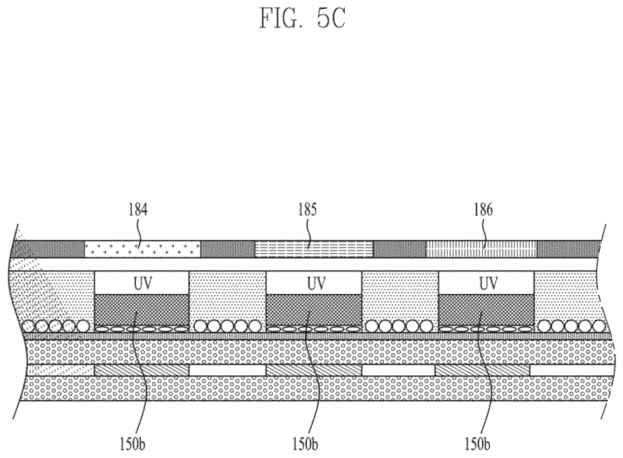

FIGS. 5A to 5C are conceptual views illustrating various examples of implementation of colors in relation to a flip-chip type semiconductor light emitting device.

Referring to FIG. 5A, each semiconductor light emitting device may be implemented as a high-power light emitting device emitting light of various colors including blue by using gallium nitride (GaN) as a main material and adding indium (In) and/or aluminum (Al).

In this case, each semiconductor light emitting device may be a red, green, or blue semiconductor light emitting device to form a unit pixel (sub-pixel). For example, red, green, and blue semiconductor light emitting devices R. G, and B may be alternately disposed, and unit pixels of red, green, and blue may constitute one pixel by the red, green and blue semiconductor light emitting devices. Thereby, a full-color display may be implemented.

Referring to FIG. 5B, the semiconductor light emitting device 150a may include a white light emitting device W having a yellow phosphor conversion layer, which is provided for each device. In this case, in order to form a unit pixel, a red phosphor conversion layer 181, a green phosphor conversion layer 182, and a blue phosphor conversion layer 183 may be disposed on the white light emitting device W. In addition, a unit pixel may be formed using a color filter repeating red, green, and blue on the white light emitting device W.

Referring to FIG. 5C, a red phosphor conversion layer 181, a green phosphor conversion layer 185, and a blue phosphor conversion layer 183 may be provided on a ultraviolet light emitting device. Not only visible light but also ultraviolet (UV) light may be used in the entire region of the semiconductor light emitting device. In an embodiment, UV may be used as an excitation source of the upper phosphor in the semiconductor light emitting device.

Referring back to this example, the semiconductor light emitting device is positioned on the conductive adhesive layer to constitute a unit pixel in the display device. Since the semiconductor light emitting device has excellent luminance, individual unit pixels may be configured despite even when the semiconductor light emitting device has a small size.

Regarding the size of such an individual semiconductor light emitting device, the length of each side of the device may be, for example, 80 μm or less, and the device may have a rectangular or square shape. When the semiconductor light emitting device has a rectangular shape, the size thereof may be less than or equal to 20 μm×80 μm.

In addition, even when a square semiconductor light emitting device having a side length of 10 μm is used as a unit pixel, sufficient brightness to form a display device may be obtained.

Therefore, for example, in case of a rectangular pixel having a unit pixel size of 600 μm×300 μm (i.e., one side by the other side), a distance of a semiconductor light emitting device becomes sufficiently long relatively.

Thus, in this case, it is able to implement a flexible display device having high image quality over HD image quality.

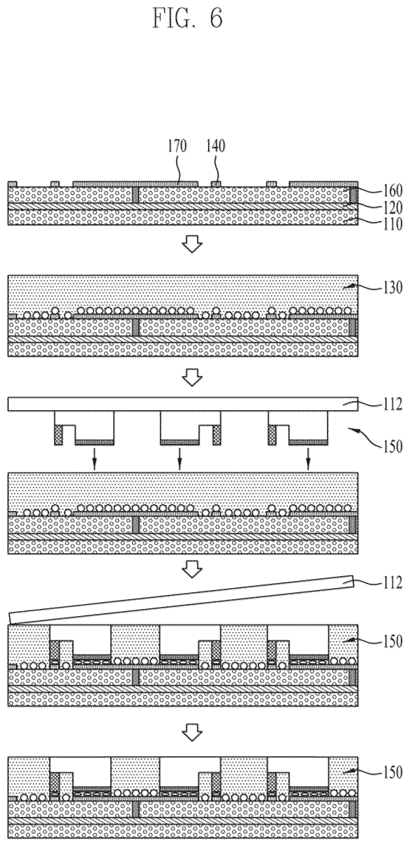

The above-described display device using the semiconductor light emitting device may be prepared by a new fabricating method. Such a fabricating method will be described with reference to FIG. 6 as follows.

FIG. 6 shows cross-sectional views of a method of fabricating a display device using a semiconductor light emitting device according to the present disclosure.

Referring to FIG. 6, first of all, a conductive adhesive layer 130 is formed on an insulating layer 160 located between an auxiliary electrode 170 and a second electrode 140. The insulating layer 160 is tacked on a wiring substrate 110. On the wiring substrate 110, a first electrode 120, the auxiliary electrode 170 and the second electrode 140 are disposed. In this case, the first electrode 120 and the second electrode 140 may be disposed in mutually orthogonal directions, respectively. In order to implement a flexible display device, the wiring substrate 110 and the insulating layer 160 may include glass or polyimide (PI) each.

For example, the conductive adhesive layer 130 may be implemented by an anisotropic conductive film. To this end, an anisotropic conductive film may be coated on the substrate on which the insulating layer 160 is located.

Subsequently, a temporary substrate 112, on which a plurality of semiconductor light emitting devices 150 configuring individual pixels are located to correspond to locations of the auxiliary electrode 170 and the second electrodes 140, is disposed in a manner that the semiconductor light emitting device 150 confronts the auxiliary electrode 170 and the second electrode 140.

In this regard, the temporary 112 substrate 112 is a growing substrate for growing the semiconductor light emitting device 150 and may include a sapphire or silicon substrate.

The semiconductor light emitting device is configured to have a space and size for configuring a display device when formed in unit of wafer, thereby being effectively used for the display device.

Subsequently, the wiring substrate 110 and the temporary substrate 112 are thermally compressed together. By the thermocompression, the wiring substrate 110 and the temporary substrate 112 are bonded together. Owing to the property of an anisotropic conductive film having conductivity by thermocompression, only a portion among the semiconductor light emitting device 150, the auxiliary electrode 170 and the second electrode 140 has conductivity, via which the electrodes and the semiconductor light emitting device 150 may be connected electrically. In this case, the semiconductor light emitting device 150 is inserted into the anisotropic conductive film, by which a partition may be formed between the semiconductor light emitting devices 150.

Then the temporary substrate 112 is removed. For example, the temporary substrate 112 may be removed using Laser Lift-Off (LLO) or Chemical Lift-Off (CLO).

Finally, by removing the temporary substrate 112, the semiconductor light emitting devices 150 exposed externally. If necessary; the wiring substrate 110 to which the semiconductor light emitting devices 150 are coupled may be coated with silicon oxide (SiOx) or the like to form a transparent insulating layer (not shown).

In addition, a step of forming a phosphor layer on one side of the semiconductor light emitting device 150 may be further included. For example, the semiconductor light emitting device 150 may include a blue semiconductor light emitting device emitting Blue (B) light, and a red or green phosphor for converting the blue (B) light into a color of a unit pixel may form a layer on one side of the blue semiconductor light emitting device.

The above-described fabricating method or structure of the display device using the semiconductor light emitting device may be modified into various forms. For example, the above-described display device may employ a vertical semiconductor light emitting device.

Furthermore, a modification or embodiment described in the following may use the same or similar reference numbers for the same or similar configurations of the former example and the former description may apply thereto.

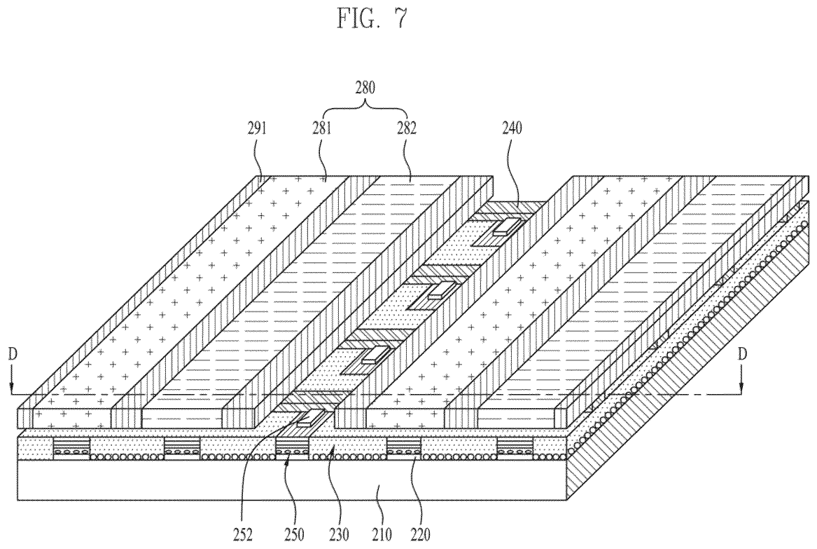

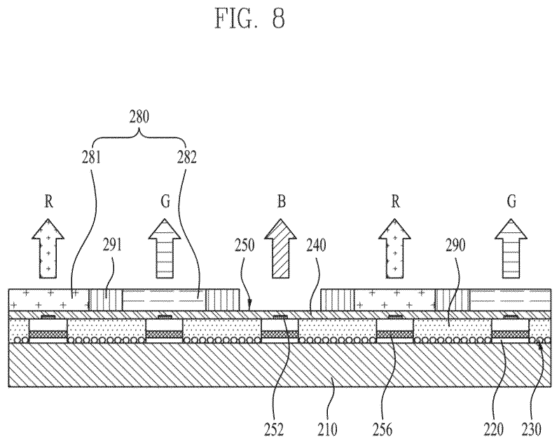

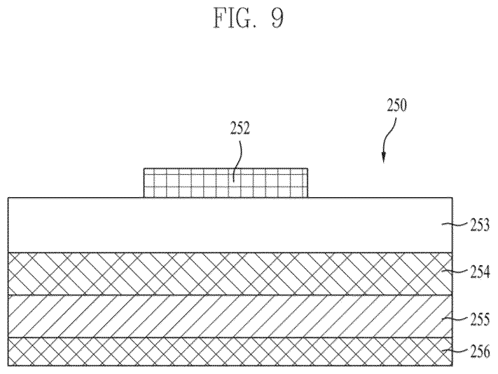

FIG. 7 is a perspective diagram of a display device using a semiconductor light emitting device according to another embodiment of the present disclosure, FIG. 8 is a cross-sectional diagram taken along a cutting line D-D shown in FIG. 8, and FIG. 9 is a conceptual diagram showing a vertical type semiconductor light emitting device shown in FIG. 8.

Referring to the present drawings, a display device may employ a vertical semiconductor light emitting device of a Passive Matrix (PM) type.

The display device includes a substrate 210, a first electrode 220, a conductive adhesive layer 230, a second electrode 240 and at least one semiconductor light emitting device 250.

The substrate 210 is a wiring substrate on which the first electrode 220 is disposed and may contain polyimide (PI) to implement a flexible display device. Besides, the substrate 210 may use any substance that is insulating and flexible.

The first electrode 210 is located on the substrate 210 and may be formed as a bar type electrode that is long in one direction. The first electrode 220 may be configured to play a role as a data electrode.

The conductive adhesive layer 230 is formed on the substrate 210 where the first electrode 220 is located. Like a display device to which a light emitting device of a flip chip type is applied, the conductive adhesive layer 230 may include one of an Anisotropic Conductive Film (ACF), an anisotropic conductive paste, a conductive particle contained solution and the like. Yet, in the present embodiment, a case of implementing the conductive adhesive layer 230 with the anisotropic conductive film is exemplified.

After the conductive adhesive layer has been placed in the state that the first electrode 220 is located on the substrate 210, if the semiconductor light emitting device 250 is connected by applying heat and pressure thereto, the semiconductor light emitting device 250 is electrically connected to the first electrode 220. In doing so, the semiconductor light emitting device 250 is preferably disposed to be located on the first electrode 220.

If heat and pressure is applied to an anisotropic conductive film, as described above, since the anisotropic conductive film has conductivity partially in a thickness direction, the electrical connection is established. Therefore, the anisotropic conductive film is partitioned into a conductive portion and a non-conductive portion.

Furthermore, since the anisotropic conductive film contains an adhesive component, the conductive adhesive layer 230 implements mechanical coupling between the semiconductor light emitting device 250 and the first electrode 220 as well as mechanical connection.

Thus, the semiconductor light emitting device 250 is located on the conductive adhesive layer 230, via which an individual pixel is configured in the display device. As the semiconductor light emitting device 250 has excellent luminance, an individual unit pixel may be configured in small size as well. Regarding a size of the individual semiconductor light emitting device 250, a length of one side may be equal to or smaller than 80 μm for example and the individual semiconductor light emitting device 250 may include a rectangular or square element. For example, the rectangular element may have a size equal to or smaller than 20 μm×80 μm.

The semiconductor light emitting device 250 may have a vertical structure.

Among the vertical type semiconductor light emitting devices, a plurality of second electrodes 240 respectively and electrically connected to the vertical type semiconductor light emitting devices 250 are located in a manner of being disposed in a direction crossing with a length direction of the first electrode 220.

Referring to FIG. 9, the vertical type semiconductor light emitting device 250 includes a p-type electrode 256, a p-type semiconductor layer 255 formed on the p-type electrode 256, an active layer 254 formed on the p-type semiconductor layer 255, an n-type semiconductor layer 253 formed on the active layer 254, and an n-type electrode 252 formed on then-type semiconductor layer 253. In this case, the p-type electrode 256 located on a bottom side may be electrically connected to the first electrode 220 by the conductive adhesive layer 230, and the n-type electrode 252 located on a top side may be electrically connected to a second electrode 240) described later. Since such a vertical type semiconductor light emitting device 250 may dispose the electrodes at top and bottom, it is considerably advantageous in reducing a chip size.

Referring to FIG. 8 again, a phosphor layer 280 may formed on one side of the semiconductor light emitting device 250. For example, the semiconductor light emitting device 250) may include a blue semiconductor light emitting device 251 emitting blue (B) light, and a phosphor layer 280 for converting the blue (B) light into a color of a unit pixel may be provided. In this regard, the phosphor layer 280 may include a red phosphor 281 and a green phosphor 282 configuring an individual pixel.

Namely, at a location of configuring a red unit pixel, the red phosphor 281 capable of converting blue light into red (R) light may be stacked on a blue semiconductor light emitting device. At a location of configuring a green unit pixel, the green phosphor 282 capable of converting blue light into green (G) light may be stacked on the blue semiconductor light emitting device. Moreover, the blue semiconductor light emitting device may be singly usable for a portion that configures a blue unit pixel. In this case, the unit pixels of red (R), green (G) and blue (B) may configure a single pixel.

Yet, the present disclosure is non-limited by the above description. In a display device to which a light emitting device of a flip chip type is applied, as described above, a different structure for implementing blue, red and green may be applicable.

Regarding the present embodiment again, the second electrode 240 is located between the semiconductor light emitting devices 250 and connected to the semiconductor light emitting devices electrically. For example, the semiconductor light emitting devices 250 are disposed in a plurality of columns, and the second electrode 240 may be located between the columns of the semiconductor light emitting devices 250.

Since a distance between the semiconductor light emitting devices 250 configuring the individual pixel is sufficiently long, the second electrode 240 may be located between the semiconductor light emitting devices 250.

The second electrode 240 may be formed as an electrode of a bar type that is long in one direction and disposed in a direction vertical to the first electrode.

In addition, the second electrode 240 and the semiconductor light emitting device 250 may be electrically connected to each other by a connecting electrode protruding from the second electrode 240. Particularly, the connecting electrode may include a n-type electrode of the semiconductor light emitting device 250. For example, the n-type electrode is formed as an ohmic electrode for ohmic contact, and the second electrode covers at least one portion of the ohmic electrode by printing or deposition. Thus, the second electrode 240 and the n-type electrode of the semiconductor light emitting device 250 may be electrically connected to each other.

Referring to FIG. 8 again, the second electrode 240 may be located on the conductive adhesive layer 230. In some cases, a transparent insulating layer (not shown) containing silicon oxide (SiOx) and the like may be formed on the substrate 210 having the semiconductor light emitting device 250 formed thereon. If the second electrode 240 is placed after the transparent insulating layer has been formed, the second electrode 240 is located on the transparent insulating layer. Alternatively, the second electrode 240 may be formed in a manner of being spaced apart from the conductive adhesive layer 230 or the transparent insulating layer.

If a transparent electrode of Indium Tin Oxide (ITO) or the like is sued to place the second electrode 240 on the semiconductor light emitting device 250, there is a problem that ITO substance has poor adhesiveness to an n-type semiconductor layer. Therefore, according to the present disclosure, as the second electrode 240 is placed between the semiconductor light emitting devices 250, it is advantageous in that a transparent electrode of ITO is not used. Thus, light extraction efficiency may be improved using a conductive substance having good adhesiveness to an n-type semiconductor layer as a horizontal electrode without restriction on transparent substance selection.

Referring to FIG. 8 again, a partition 290 may be located between the semiconductor light emitting devices 250. Namely, in order to isolate the semiconductor light emitting device 250 configuring the individual pixel, the partition 290 may be disposed between the vertical type semiconductor light emitting devices 250. In this case, the partition 290 may play a role in separating the individual unit pixels from each other and be formed with the conductive adhesive layer 230 as an integral part. For example, by inserting the semiconductor light emitting device 250 in an anisotropic conductive film, a base member of the anisotropic conductive film may form the partition.

In addition, if the base member of the anisotropic conductive film is black, the partition 290 may have reflective property as well as a contrast ratio may be increased, without a separate block insulator.

For another example, a reflective partition may be separately provided as the partition 190. The partition 290 may include a black or white insulator depending on the purpose of the display device.

In case that the second electrode 240 is located right onto the conductive adhesive layer 230 between the semiconductor light emitting devices 250, the partition 290 may be located between the vertical type semiconductor light emitting device 250 and the second electrode 240 each. Therefore, an individual unit pixel may be configured using the semiconductor light emitting device 250. Since a distance between the semiconductor light emitting devices 250 is sufficiently long, the second electrode 240 may be placed between the semiconductor light emitting devices 250. And, it may bring an effect of implementing a flexible display device having HD image quality.

In addition, as shown in FIG. 8, a black matrix 291 may be disposed between the respective phosphors for the contrast ratio improvement. Namely, the black matrix 291 may improve the contrast between light and shade.

In the display device using the semiconductor light emitting device according to the present disclosure described above, the semiconductor light emitting device is disposed on the wiring substrate in the flip-chip type and used as an individual pixel.

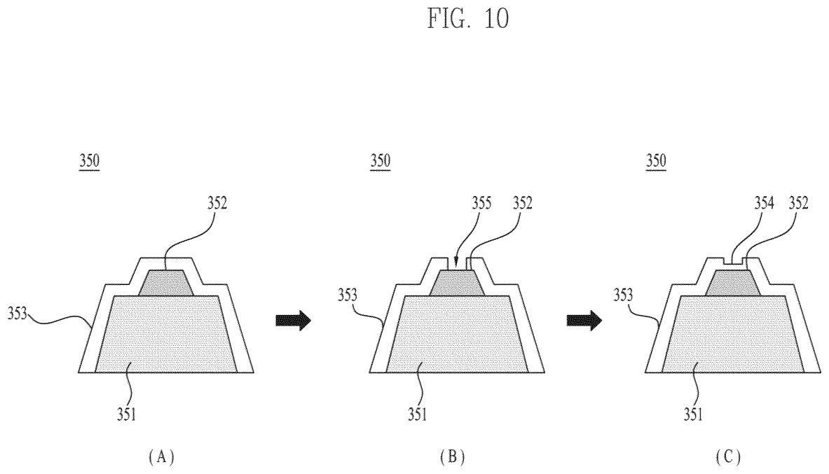

FIG. 10 is a schematic cross-sectional view illustrating an example of a semiconductor light emitting device of a display device using a semiconductor light emitting device according to an embodiment of the present disclosure.

Referring to FIG. 10, a semiconductor light emitting device 350 used in a display device using a semiconductor light emitting device according to an embodiment of the present disclosure may include a semiconductor layer 351, a first-type electrode (not shown) disposed below the semiconductor layer 351, a second-type electrode 352 disposed on the semiconductor layer 351, and a passivation layer 353 disposed on an outer surface of the semiconductor layer 351 and the second-type electrode 352.

For example, the semiconductor light emitting device 350 shown in FIG. 10 may be a vertical light emitting diode (LED). The first-type electrode may be a n-type electrode or a p-type electrode. In this case, the second-type electrode 352 may be a p-type electrode or a n-type electrode.

According to a manufacturing method of the semiconductor light emitting device 350, the second-type electrode 352 may be a p-type electrode or a n-type electrode, and accordingly, the first-type electrode may be a n-type electrode or a p-type electrode. In FIG. 10, for convenience of description, the first-type electrode positioned below the semiconductor layer 351 is not shown, but one of ordinary skill in the art will know that a first-type electrode facing the second-type electrode 352 is present. The passivation layer 353 may also be positioned on a side surface of the first-type electrode.

To manufacture a display device using a semiconductor light emitting device according to an embodiment, the semiconductor light emitting device 350 may be provided in the form of FIG. 10(A). That is, the semiconductor light emitting device 350 may be prepared in a state in which the passivation layer 353 covers the second-type electrode 352.

That is, as shown in FIG. 10(A), the semiconductor light emitting device 350 may be prepared by forming the passivation layer 353 to cover an upper side of the second-type electrode 352.

Thereafter, as shown in FIG. 10(B), the second-type electrode 352 may be opened by removing the passivation layer 353 covering the upper side of the second-type electrode 352. That is, the second-type electrode 352 may be exposed to the outside.

In general, in a state in which the second-type electrode 352 is exposed to the outside, the second-type electrode 352 may be assembled to a substrate for manufacturing a display device. However, according to an embodiment of the present disclosure, as shown in FIG. 10(C), the passivation layer 354 may be additionally formed on the upper side of the second-type electrode 352.

Referring to FIG. 10(C), the passivation layer 354 (hereinafter, referred to as the alignment passivation layer) formed on the second-type electrode 352 may have a thickness less than a thickness of the passivation layer 353 disposed on the outer surface of the semiconductor light emitting device 350.

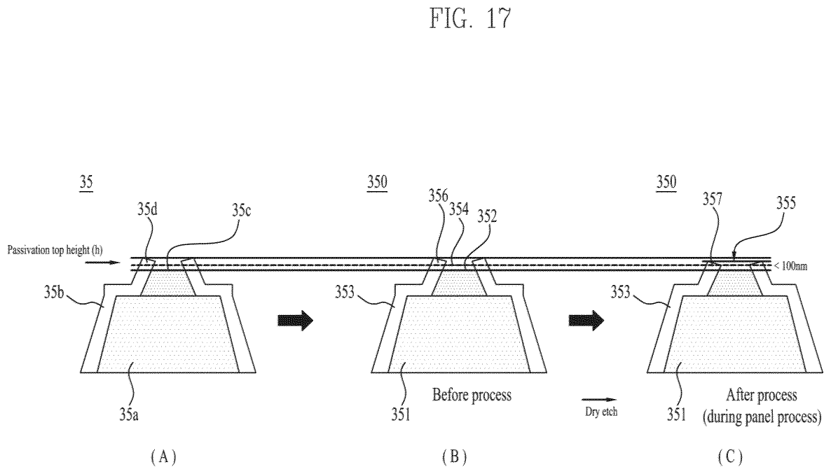

Accordingly, the passivation layer 357 (see FIG. 17) positioned higher than the alignment passivation layer 354 on a peripheral portion of the alignment passivation layer 354 and the alignment passivation layer 354 may be disposed on the second-type electrode 352.

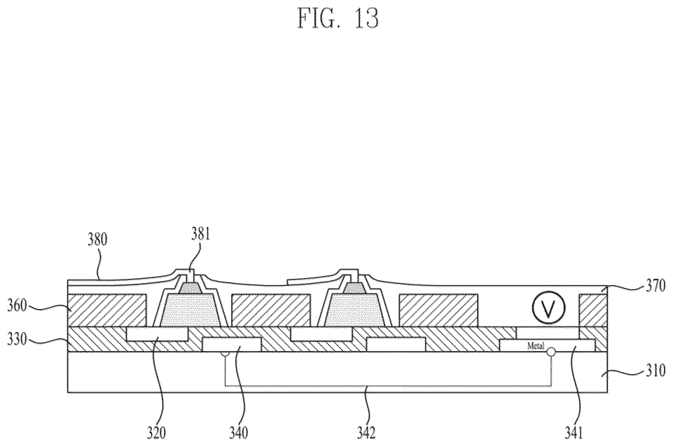

In a panel process, the passivation layer 357 positioned higher than the alignment passivation layer 354 may be partially removed when an inclined coating layer 370 (see FIG. 13) covering the upper side of the semiconductor light emitting device 350 is opened for connection of a second electrode 380 (see FIG. 13).

Accordingly, the passivation layer 357 may help the second electrode 380 to be connected to the second-type electrode 352 of the semiconductor light emitting device 350 at an accurate position without a separate alignment process. Accordingly, the passivation layer 357 may be referred to as an alignment adjuster. Hereinafter, the passivation layer 357 and the alignment adjuster positioned higher than the alignment passivation layer 354 may refer to the same entity, and the same reference numeral 357 will be used.

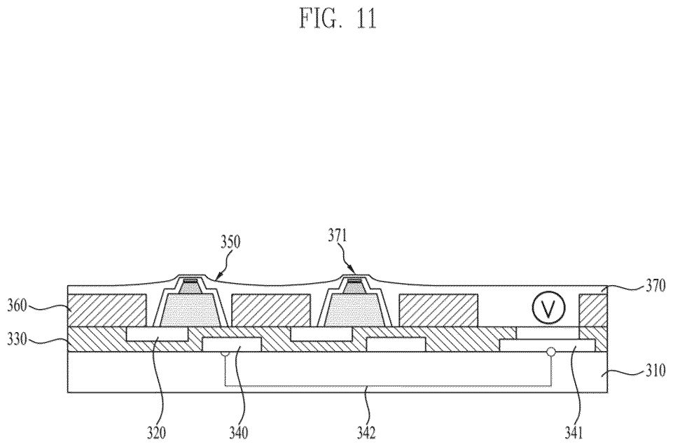

Hereinafter, a process of manufacturing a display device using a semiconductor light emitting device according to an embodiment of the present disclosure will be described in detail with reference to FIGS. 11 to 13.

FIG. 11 is a cross-sectional view illustrating a state in which a semiconductor light emitting device is assembled and an inclined coating layer is formed as one operation of a manufacturing process of a display device using a semiconductor light emitting device according to an embodiment of the present disclosure.

According to the manufacturing process of the display device according to an embodiment of the present disclosure, a partition wall 360 defining a plurality of unit pixel areas may be formed on the substrate 310, and a process of preparing a substrate assembly in which a first electrode 320 and an assembly electrode 340 are located may be performed in each of the unit pixel areas.

In the substrate assembly, the assembly electrode 340 may be positioned together with the first electrode 320 in each unit pixel area. In addition, the assembly electrodes 340 located in respective unit pixel areas may be connected to each other by a connection line 342. Accordingly, each unit pixel area voltage signal (electric field) may be applied through the signal applying unit 341 connected to the connection line 342.

Due to such a voltage signal (electric field), the plurality of semiconductor light emitting devices 350 may be assembled in each unit element area by a dielectrophoresis (DEP) phenomenon.

As shown in FIG. 10, the semiconductor layer 351 and the second-type electrode 352 may be sequentially disposed on the first-type electrode (not shown), and a process of preparing the plurality of semiconductor light emitting devices 350 having the passivation layer 353 formed on the outer surfaces of the semiconductor layer 351 and the second-type electrode 352 may be performed.

As described above, the semiconductor light emitting device 350 may include the alignment passivation layer 354 and the alignment adjuster 357. That is, the alignment passivation layer 354 may be formed on the second-type electrode 352 on the semiconductor light emitting device 350.

A process of preparing the substrate assembly and a process of preparing the plurality of semiconductor light emitting devices 350 may be independently performed. That is, the process of preparing the substrate assembly and the process of preparing the plurality of semiconductor light emitting devices 350 may not be performed in a time series.

A process of installing the semiconductor light emitting device 350 may be performed such that the first electrode 320 and the first-type electrode of the semiconductor light emitting device 350 are electrically connected to each other in a unit pixel area of the prepared substrate assembly.

In this case, when a voltage signal having a predetermined frequency range (high frequency) is applied to the corresponding assembly electrode 340 through the signal applying unit 341, the semiconductor light emitting device 350 located in the corresponding unit element area or moving to the corresponding unit element area is attracted toward the assembly electrode 340 by a DEP quenching phenomenon due to a DEP fault phenomenon. Accordingly, the semiconductor light emitting device 350 may be assembled to the corresponding assembly electrode 340. In this case, the semiconductor light emitting device 350 may be electrically connected to the first electrode 320 in the unit pixel area.

Thereafter, an operation of forming the inclined coating layer 370 on the surface including the semiconductor light emitting device 350 and the partition wall 360 may be performed.

When the above-described operations are performed, the state shown in FIG. 11 may be achieved.

Referring to FIG. 11, the inclined coating layer 370 may have a high inclination at an upper side 371 of the semiconductor light emitting device 350 assembled in the unit pixel area. That is, the unit pixel area may have a low height (thickness) between the unit pixel area and the unit pixel area, and may have a great height (thickness) at the upper portion 371 of the unit pixel area.

An operation of forming the inclined coating layer 370 may be performed by applying an insulator material having a low viscosity on a surface including the semiconductor light emitting device 350 and the partition wall 360. That is, the inclination of the inclined coating layer 370 may be naturally formed according to the viscosity of the insulator material constituting the inclined coating layer 370.

In other words, since the portion in which the semiconductor light emitting device 350 is assembled is higher than the peripheral partition wall 360, the inclination of the inclined coating layer 370 may be naturally formed due to a height difference between the semiconductor light emitting device 350 and the partition wall 360.

For example, an insulator material of the inclined coating layer 370 may include a photoresist (PR) with low viscosity. The viscosity of the low viscosity photo resist may be lower than that of the partition wall 370.

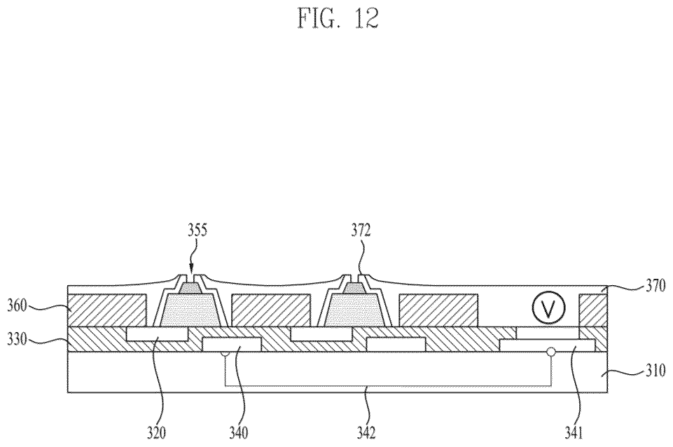

FIG. 12 is a cross-sectional schematic view illustrating a method of manufacturing a display device using a semiconductor light emitting device according to an embodiment of the present disclosure, in which an inclined coating layer is opened to open a second-type electrode.

Referring to FIG. 12, an upper surface of the inclined coating layer 370 may be entirely etched to open the second-type electrode 352 of the semiconductor light emitting device 350.

As described above, the alignment passivation layer 354 positioned on the second-type electrode 352 of the semiconductor light emitting device 350 is etched together in the process of entirely etching the upper surface of the inclined coating layer 370 formed of the low viscosity photoresist, and thus the opening 355 may be formed on the second-type electrode 352 of the semiconductor light emitting device 350.

Accordingly, the opening 355 may open an accurate position of the second-type electrode 352 of the semiconductor light emitting device 350. In other words, a separate etching mask is not required to open the second-type electrode 352 of the semiconductor light emitting device 350. Furthermore, alignment errors that may occur when the etching mask is used may not occur. In addition, a portion of the alignment adjuster 357 may be etched together in this process. Accordingly, the height of the alignment adjuster 357 may be 100 nm or less. This will be described in detail below with reference to the drawings.

As described above, in the process of entirely etching the upper surface of the inclined coating layer 370 formed of the low-viscosity photoresist, the inclined coating layer 370 having a predetermined thickness may be etched, and the opening 372 of the inclined coating layer 370 may be formed on the semiconductor light emitting device 350.

In addition, the alignment passivation layer 354 positioned on the second-type electrode 352 of the semiconductor light emitting device 350 may be etched together to form an opening 355 on the second-type electrode 352 of the semiconductor light emitting device 350.

As described above, the opening 372 of the inclined coating layer 370 may accurately coincide with the opening 355 opening the second-type electrode 352 of the semiconductor light emitting device 350.

FIG. 13 is a cross-sectional view illustrating a state in which a second electrode electrically connected to a second-type electrode is formed as one operation of a process of manufacturing a display device using a semiconductor light emitting device according to an embodiment of the present disclosure.

Referring to FIG. 13, a process of forming the second electrode 380 electrically connected to the second-type electrode 352 of the semiconductor light emitting device 350 on the inclined coating layer 370 may be performed.

The second-type electrode 352 of the semiconductor light emitting device 350 opened by the above process may be electrically connected to the second electrode 380 through the connection portion 381. The connection part 381 may be located in the opening 372 of the inclined coating layer 370. In addition, the connection portion 381 may be disposed in the opening 355 opening the second-type electrode 352 of the semiconductor light emitting device 350.

As described above, the inclined coating layer 370 may be entirely etched to connect the second electrode 380 and the second-type electrode 352 of the semiconductor light emitting device 350 at an accurate position.

The inclined coating layer 370 may be formed to have a small thickness, and thus the overall thickness of the display device may be reduced.

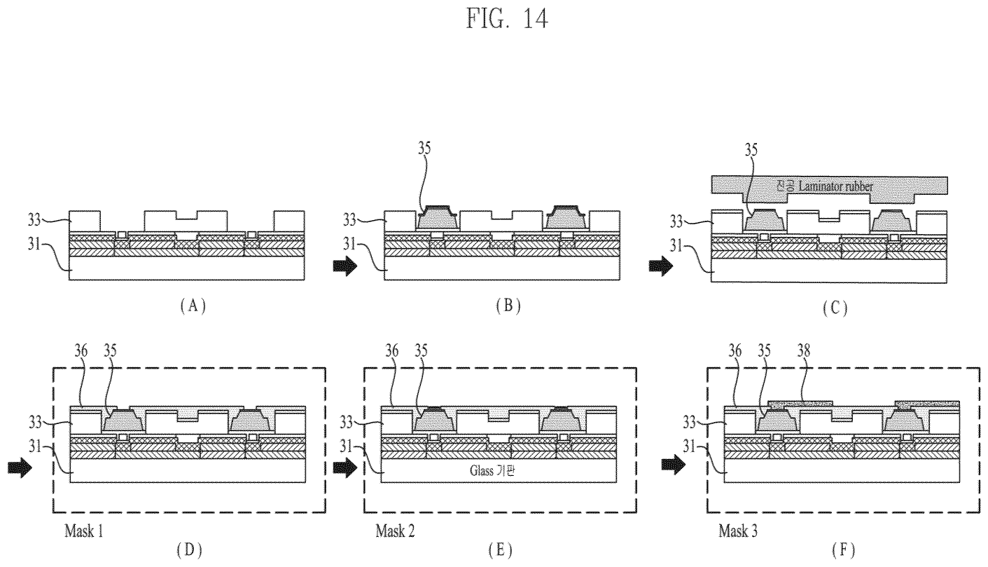

FIG. 14 is a diagram illustrating a process of manufacturing a display device using a semiconductor light emitting device as a comparative example.

First, FIG. 14(A) shows a process of forming the partition wall 33, and FIG. 14B shows an assembly process of the semiconductor light emitting device 35.

Then, FIG. 14(C) illustrates a bonding process of the semiconductor light emitting device 35. The bonding process of the semiconductor light emitting device 35 may be performed by compressing the semiconductor light emitting device 35 using a vacuum laminator rubber.

Referring to FIG. 14, processes of FIGS. 14(D), 14(E) and 14(F) are required to electrically connect the second electrode 38 to the semiconductor light emitting device 35. That is, three mask alignment processes are required.

That is, as shown in FIG. 14(D), a process of opening a passivation layer of the semiconductor light emitting device 35 is performed, and in this case, a first photo process may be performed to open an accurate position of the passivation layer of the semiconductor light emitting device 35. For this first photo process, a photo mask may be used once (Mask 1).

Then, as shown in FIG. 14(E), an insulating layer may be formed and a planarization process may be performed, and to this end, a second photo process may be performed. For this second photo process, a photo mask may be used once (Mask 2).

Then, as shown in FIG. 14(F), a process of forming the second electrode 38 may be performed. To this end, a third photo process may be performed. For this third photo process, a photo mask may be used once (Mask 3).

As described above, according to the conventional display manufacturing process, three masks may be used while the passivation opening process (FIG. 14D), the planarization process (FIG. 14(E)), and the lighting wiring process (FIG. 14(F)) are performed in subsequent processes.

A photo process using the three masks may be accumulated, and an error due to alignment tolerance for each process may be accumulated. Such accumulation of errors may lead to problems such as luminance non-uniformity and unlighting of a display device. In addition, due to the accumulation of the alignment error, problems such as luminance non-uniformity and non-lighting of the display device may further occur.

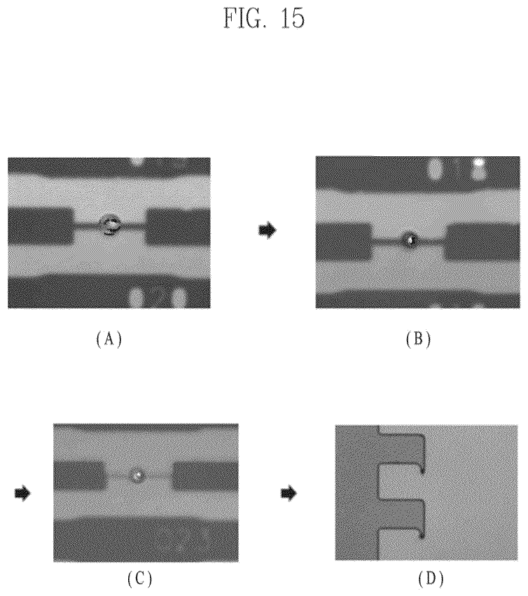

FIG. 15 is an actual image of an alignment error that may occur in the process of FIG. 14.

During the photo process, a mis-alignment of at least 4 μm may occur in consideration of an alignment precision of conventional exposure equipment of about +2 μm and a chip assembly tolerance of about +2 μm according to a transfer process.

FIG. 15(A) shows an example of an alignment error that may occur during an assembly process of the semiconductor light emitting device 35. For example, side bias may occur in a unit element area of the semiconductor light emitting device 35.

FIG. 15(B) shows an example of alignment errors that may occur by the passivation opening process (FIG. 14(D)). For example, the second-type electrode of the semiconductor light emitting device 35 may not be opened at an accurate position.

FIG. 15(C) shows an example of an alignment error that may occur by a planarization process (FIG. 14(E)). A state in which an alignment error occurs is shown.

FIG. 15(D) shows an example of an alignment error that may be generated by a process of forming a lighting line (second electrode) (FIG. 14(F)). A state in which an alignment error occurs is also shown

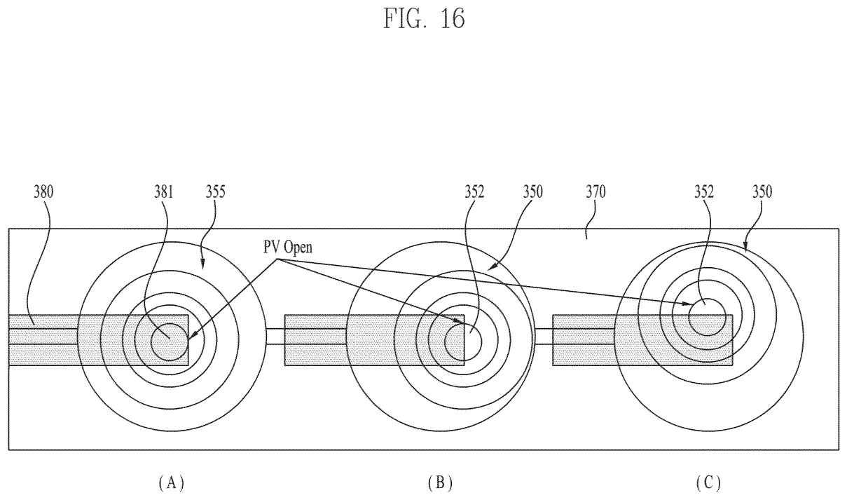

FIG. 16 is a schematic diagram illustrating various states in which a lighting wire (second electrode) is connected.

Referring to FIG. 16(A), according to the manufacturing according to an embodiment of the present disclosure described above, the inclined coating layer 370 may be entirely etched to connect the second electrode 380 and the second-type electrode 352 of the semiconductor light emitting device 350 at an accurate position.

The second-type electrode 352 of the semiconductor light emitting device 350 may be electrically connected at an accurate position without an alignment error with the second electrode 380 through the connection portion 381 of the second electrode 380.

On the other hand, FIGS. 16(B) and 16(C) show a state in which the second electrode 380 and the second-type electrode 352 of the semiconductor light emitting device 350 are not accurately connected by the alignment error described above.

For example, referring to FIG. 16 (B), although the second electrode 380 is formed at a normal position with respect to the partition wall, the second electrode 380 is formed in a state in which the semiconductor light emitting device 350 is assembled to a right side, and thus the second electrode 380 is not electrically connected to the second-type electrode 352 of the semiconductor light emitting device 350 in a sufficient contact area.

As another example, referring to FIG. 16(B), although the second electrode 380 is formed at a normal position with respect to the partition wall, the second electrode 380 is formed in a state in which the semiconductor light emitting device 350 is assembled to an upper side, and thus the second electrode 380 is not electrically connected to the second-type electrode 352 of the semiconductor light emitting device 350 in a sufficient contact area.

However, in a state in which the semiconductor light emitting device 350 is assembled in a state in which the semiconductor light emitting device 350 is inclined upward, the position of the second-type electrode 352 may be accurately opened according to the embodiment of the present disclosure described above, and thus an electrical connection may be performed with a sufficient contact area.

FIG. 17 is a cross-sectional diagram illustrating a shape of an alignment adjusting unit of a semiconductor light emitting device in a process of manufacturing a display device using a semiconductor light emitting device according to an embodiment of the present disclosure.

First, FIG. 17(A) corresponds to the comparative example described with reference to FIG. 14. Referring to FIG. 17(A), the passivation layer may include a first portion 35 b positioned on a side surface of the semiconductor layer 35a and a second portion 35d positioned higher than the second-type electrode 35c.

In this case, the second portion 35d of the passivation layer corresponds to a portion formed in a process using the mask. A height (thickness) of the second portion 35d may be 100 nm or more. In addition, the second portion 35d may not be formed at an accurate position due to an alignment error.

FIG. 17(B) shows a state in which the semiconductor light emitting device 350 is assembled in a unit element area according to an embodiment of the present disclosure.

In this case, the alignment passivation layer 354 and the passivation layer 356 (alignment adjuster) positioned higher than the alignment passivation layer 354 may be disposed on the peripheral portion of the alignment passivation layer 354 and the alignment passivation layer 354 on the second-type electrode 352.

The alignment adjuster 356 may be etched together when the inclined coating layer 370 is entirely etched, and thus the height of the alignment adjuster 356 may be lowered as shown in FIG. 17(C).

That is, referring to FIG. 17(C), the height of the alignment adjuster 357 before etching may be lowered to the height of the alignment adjuster 356 after the etching. As described above, the height (thickness) of the alignment adjuster 356 may be 100 nm or less.

As illustrated in the drawing, when the inclined coating layer 370 is entirely etched, dry etching may be used.

As described above, the height of the alignment adjuster 356 lowered by the manufacturing process may further increase a contact force between the second electrode 380 and the second electrode 355.

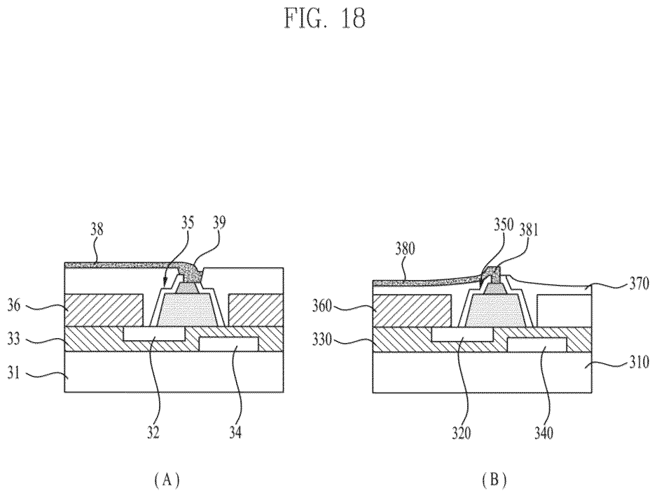

FIG. 18 is a schematic cross-sectional view illustrating a structure of a pixel according to a comparative example and a structure of a pixel according to an embodiment of the present disclosure.

As described above, according to the manufacturing process of a conventional display device according to the comparative example, as shown in FIG. 18(A), a thick coating layer 37 may be formed to relatively increase the overall thickness of the display device.

An alignment error due to the use of three masks may occur, and thus it may be difficult for the semiconductor light emitting device 35 to be electrically connected to the second electrode 38 with a sufficient contact area.

On the other hand, referring to FIG. 18(B), the inclined coating layer 370 may be formed to have a thin thickness, and thus the overall thickness of the display device may be reduced.

In addition, as described above, the height of the alignment adjuster 356 lowered by the manufacturing process may further increase the contact force between the second electrode 380 and the second electrode 355.

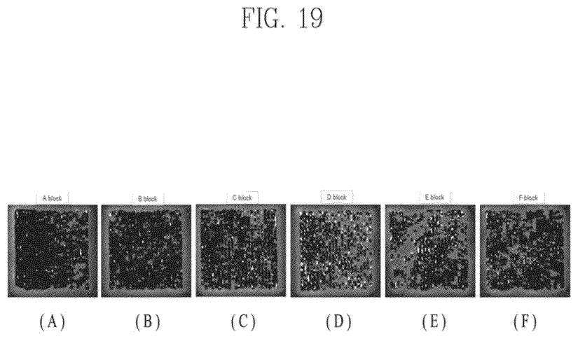

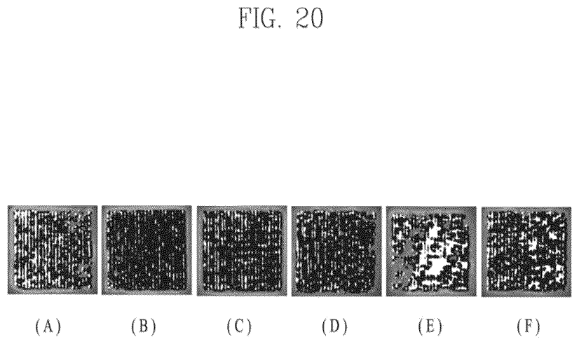

FIG. 19 is an actual image showing a pixel lighting state in each part of a display device using a semiconductor light emitting device as a comparative example. FIG. 20 is an actual image showing a pixel lighting state in each part of a display device using a semiconductor light emitting device according to an embodiment of the present disclosure.

FIGS. 19 and 20 show a pixel lighting state for the same area. Comparing the images of FIGS. 19 and 20, the pixel lighting state of FIG. 20 is significantly excellent. In addition, it may be seen that the uniformity of luminance is greatly improved.

As described above, according to an embodiment of the present disclosure, an alignment error may be greatly reduced, and an electrical contact between the semiconductor light emitting device and the second electrode (lighting electrode) may be performed at an accurate position.

As described above, according to an embodiment of the present disclosure, the manufacturing process is simplified through the design and panel process improvement of the semiconductor light emitting device, thereby minimizing alignment tolerance which may occur in the panel photo process, thereby improving manufacturing yield.

Specifically, when the semiconductor light emitting device chip is fixed by forming the inclined coating layer using the low viscosity photoresist, the planarization of the metal wiring may be simultaneously performed when the second electrode (upper wiring: the lighting electrode) is connected. Accordingly, the photo process may be simplified from three operations to one operation.

In addition, an alignment error may be minimized in a post-panel process to ensure a maximum contact area of the semiconductor light emitting device chip electrode and the second electrode (an upper wiring and a lighting electrode).

Therefore, when the semiconductor light emitting device chip is assembled at the right position of the chip, the semiconductor light emitting device chip electrode having a size of about 3 μm may be connected to the wire, and the alignment error may be minimized to allow the semiconductor light emitting device chip to be connected to the side surface even though the semiconductor light emitting device chip is positioned on the side surface.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

### INDUSTRIAL AVAILABILITY

The present disclosure provides a display device using a semiconductor light emitting device such as a micro light emitting diode (LED) and a method of manufacturing the same.

1. A display device using a semiconductor light emitting device comprising:
a substrate;
a partition wall defining a unit pixel area;
a first electrode disposed in the unit pixel area;
a semiconductor light emitting device installed with a first-type electrode electrically connected to the first electrode within the unit pixel area;
an inclined coating layer formed on the semiconductor light emitting device and the partition wall and having a high inclination at an upper side of the semiconductor light emitting device; and
a second electrode electrically connected to a second-type electrode of the semiconductor light emitting device on the inclined coating layer.

2. The display device of claim 1, wherein the inclined coating layer has a symmetrical inclination with respect to the unit pixel area in which the semiconductor light emitting device is installed.

3. The display device of claim 1, wherein the inclined coating layer is formed of a photoresist with a lower viscosity than a material of the partition wall.

4. The display device of claim 1, wherein a thickness of a portion of the inclined coating layer, disposed on the partition wall, is less than a thickness of a portion of the inclined coating layer, disposed on the semiconductor light emitting device.

5. The display device of claim 1, wherein the semiconductor light emitting device includes:
the first-type electrode;
a semiconductor layer disposed on the first-type electrode;
the second-type electrode disposed on the semiconductor layer; and
a passivation layer disposed on an outer surface of the semiconductor layer and the second-type electrode.

6. The display device of claim 5, wherein the passivation layer includes an alignment adjuster disposed higher than the second-type electrode on a peripheral portion of the second-type electrode.

7. The display device of claim 6, wherein the alignment adjuster is partially removed together when the inclined coating layer is opened for connection of the second electrode.

8. The display device of claim 6, wherein a height of the alignment adjuster is 100 nm or smaller.

9. The display device of claim 1, wherein an assembly electrode for assembly of the semiconductor light emitting device is disposed on one side of the first electrode of the unit pixel area.

10. A method of manufacturing a display device using a semiconductor light emitting device, the method comprising:
preparing a substrate assembly including a substrate on which a partition wall defining a plurality of unit pixel area is defined wherein a first electrode and an assembly electrode are disposed within the unit pixel area;
preparing a plurality of semiconductor light emitting devices in which a semiconductor layer and a second-type electrode are disposed on a first-type electrode, and a passivation layer is formed on an outer surface of the semiconductor layer and the second-type electrode;
installing the semiconductor light emitting device to electrically connect the first electrode and the first-type electrode within the unit pixel area;
forming an inclined coating layer on the semiconductor light emitting device and the partition wall;
opening the second-type electrode of the semiconductor light emitting device by entirely etching the inclined coating layer; and
forming a second electrode electrically connected to the second-type electrode of the semiconductor light emitting device on the inclined coating layer.

11. The method of claim 10, wherein opening of the second-type electrode includes opening the second-type electrode of the semiconductor light emitting device installed within each of the unit pixel areas.

12. The method of claim 10, wherein the inclined coating layer has a high inclination at an upper side of the semiconductor light emitting device.

13. The method of claim 10, wherein forming of the inclined coating layer includes coating a photoresist with a lower viscosity than a material of the partition wall.

14. The method of claim 10, wherein preparing of the semiconductor light emitting device includes forming the passivation layer to cover an upper side of the second-type electrode.

15. The method of claim 14, wherein a thickness of a portion of the passivation layer, covering the upper side of the second-type electrode, is less than a thickness of a portion of the passivation layer, disposed on an outer surface of the semiconductor light emitting device.

16. The method of claim 10, wherein preparing of the semiconductor light emitting device includes:
opening the second-type electrode by removing the passivation layer covering the upper side of the second-type electrode; and
forming a passivation layer having a smaller thickness than the passivation layer disposed on an outer surface of the semiconductor light emitting device on the second-type electrode.

17. The method of claim 10, wherein the passivation layer includes an alignment adjuster disposed higher than the second-type electrode on a peripheral portion of the second-type electrode.

18. The method of claim 17, wherein the alignment adjuster has a height that is lowered after the opening of the second-type electrode is performed.

19. The method of claim 17, wherein a height of the alignment adjuster is 100 nm or smaller.

20. The method of claim 10, wherein installing of the semiconductor light emitting device includes applying an electric field to the assembly electrode.
